(19) United States
(12) Patent Application Publication
(10) Pub. No.: US 2026/0113969 A1
(43) Pub. Date: Apr. 23, 2026

(54) NITRIDE SEMICONDUCTOR TRANSISTOR

(71) Applicant: SUMITOMO ELECTRIC INDUSTRIES, LTD., Osaka (JP)

(72) Inventor: Shigeki YOSHIDA, Osaka (JP)

(21) Appl. No.: 19/355,243

(22) Filed: Oct. 10, 2025

(30) Foreign Application Priority Data
Oct. 18, 2024 (JP) 2024-182944

(51) Int. Cl. H10D 30/47; H10D 62/824

(52) U.S. Cl. CPC H10D 30/474; H10D 30/475; H10D 62/824

(57) ABSTRACT

A nitride semiconductor transistor includes a first channel layer having a first upper surface with a nitrogen polarity; a ferroelectric nitride semiconductor layer deposited on the first upper surface and having a second upper surface with a first metal polarity; a second channel layer deposited on the second upper surface and having a third upper surface with a second metal polarity; and a first barrier layer deposited on the third upper surface and having a fourth upper surface with a third metal polarity.

### CROSS-REFERENCE TO RELATED APPLICATIONS

This application claims priority to Japanese Patent Application No. 2024-182944, filed Oct. 18, 2024, the entire content of which is incorporated herein by reference.

### BACKGROUND

### 1. Technical Field

The present disclosure relates to a nitride semiconductor transistor.

### 2. Description of Related Art

A high electron mobility transistor (HEMT) having a plurality of channels has been proposed.
Patent Document 1: Japanese Unexamined Patent Application No. 2014-183311

### SUMMARY

A nitride semiconductor transistor according to the present disclosure includes a first channel layer having a first upper surface with a nitrogen polarity; a ferroelectric nitride semiconductor layer deposited on the first upper surface and having a second upper surface with a first metal polarity; a second channel layer deposited on the second upper surface and having a third upper surface with a second metal polarity; and a first barrier layer deposited on the third upper surface and having a fourth upper surface with a third metal polarity.

### BRIEF DESCRIPTION OF THE DRAWINGS

FIG. 1 is a cross-sectional view illustrating a nitride semiconductor transistor according to a first embodiment;

FIG. 2 is a diagram illustrating a band structure of the nitride semiconductor transistor according to the first embodiment;

FIG. 3 is a cross-sectional view (1) illustrating a method of manufacturing the nitride semiconductor transistor according to the first embodiment;

FIG. 4 is a cross-sectional view (2) illustrating the method of manufacturing a nitride semiconductor transistor according to a first embodiment;

FIG. 5 is a cross-sectional view (3) illustrating the method of manufacturing the nitride semiconductor transistor according to the first embodiment;

FIG. 6 is a cross-sectional view (4) illustrating the method of manufacturing the nitride semiconductor transistor according to the first embodiment;

FIG. 7 is a cross-sectional view (5) illustrating the method of manufacturing the nitride semiconductor transistor according to the first embodiment;

FIG. 8 is a cross-sectional view (6) illustrating a method of manufacturing the nitride semiconductor transistor according to the first embodiment;

FIG. 9 is a cross-sectional view illustrating a nitride semiconductor transistor according to a second embodiment; and

FIG. 10 is a diagram illustrating a band structure of the nitride semiconductor transistor according to the second embodiment.

### DETAILED DESCRIPTION

Recently, there has been a growing demand for further improvement in current density.

An object of the present disclosure is to provide a nitride semiconductor transistor capable of improving current density.

According to the present disclosure, current density can be improved.

### DESCRIPTION OF EMBODIMENTS OF DISCLOSURE

First, aspects of the present disclosure are listed below.

<1> A nitride semiconductor transistor according to one aspect of the present disclosure includes a first channel layer having a first upper surface with a nitrogen polarity; a ferroelectric nitride semiconductor layer deposited on the first upper surface and having a second upper surface with a first metal polarity; a second channel layer deposited on the second upper surface and having a third upper surface with a second metal polarity; and a first barrier layer deposited on the third upper surface and having a fourth upper surface with a third metal polarity.

The first upper surface of the first channel layer has a nitrogen polarity, the second upper surface of the ferroelectric nitride semiconductor layer has a first metal polarity, the third upper surface of the second channel layer has a second metal polarity, and the fourth upper surface of the first barrier layer has a third metal polarity. Therefore, the first channel layer and the second channel layer can each contain a two-dimensional electron gas. Therefore, the current density can be improved.

<2> In <1>, the ferroelectric nitride semiconductor layer includes aluminum and at least one selected from the group consisting of scandium and yttrium. In this case, a large remanent polarization is easily obtained in the ferroelectric nitride semiconductor layer.
<3> In <1> or <2>, the first channel layer has a first lower surface opposite to the first upper surface, the second channel layer has a second lower surface opposite to the third upper surface, the first channel layer includes a first two-dimensional electron gas closer to the first upper surface than to the first lower surface, and the second channel layer includes a second two-dimensional electron gas closer to the third upper surface than to the second lower surface. In this case, the first two-dimensional electron gas is mainly generated by spontaneous polarization of the ferroelectric nitride semiconductor layer, and the second two-dimensional electron gas is generated by spontaneous polarization of the first barrier layer.
<4> In <1> or <2>, the nitride semiconductor transistor includes a second barrier layer having a fifth upper surface with a nitrogen polarity, and the first channel layer is deposited on the second barrier layer. In this case, a two-dimensional electron gas is generated in the first channel layer by the second barrier layer.
<5> In <4>, the first channel layer has a first lower surface opposite to the first upper surface, the second channel layer has a second lower surface opposite to the third upper surface, the first channel layer includes a first two-dimensional electron gas closer to the first lower surface than to the first upper surface, and the second channel layer includes a second two-dimensional electron gas closer to the third upper surface than to the second lower surface. In this case, a first two-dimensional electron gas is mainly generated by spontaneous polarization of the second barrier layer, and a second two-dimensional electron gas is generated by spontaneous polarization of the first barrier layer.
<6> In any one of <1> through <5>, the ferroelectric nitride semiconductor layer and the second channel layer are lattice-matched. In this case, a compressive strain to the second channel layer due to a lattice mismatch between the ferroelectric nitride semiconductor layer and the second channel layer does not occur, and a decrease in electron mobility caused by the compressive strain can be avoided.
<7> In any one of <1> through <6>, the ferroelectric nitride semiconductor layer includes a first nitride having a first lattice constant, the second channel layer includes a second nitride having a second lattice constant, and a ratio of the first lattice constant to the second lattice constant is equal to or greater than 99%. In this case, a compressive strain to the second channel layer due to a lattice mismatch between the ferroelectric nitride semiconductor layer and the second channel layer is less likely to occur, and a decrease in electron mobility caused by compressive strain can be easily suppressed.
<8> In any of <1> through <7>, the ferroelectric nitride semiconductor layer is an aluminum scandium nitride layer, and in the aluminum scandium nitride layer, a ratio of a number of scandium atoms to a total number of aluminum atoms and scandium atoms is equal to or less than 40%. In this case, the aluminum scandium nitride layer tends to have a wurtzite crystal structure.
<9> In <8>, in the aluminum scandium nitride layer, a ratio of a number of scandium atoms to a total number of aluminum atoms and scandium atoms is equal to or greater than 10% and equal to or less than 40%. In this case, a compressive strain to the second channel layer due to a lattice mismatch between the ferroelectric nitride semiconductor layer and the second channel layer is less likely to occur, and a decrease in electron mobility caused by the compressive strain can be easily suppressed.
<10> In any of <1> through <7>, the ferroelectric nitride semiconductor layer is an aluminum yttrium nitride layer, and in the aluminum yttrium nitride layer, a ratio of a number of yttrium atoms to a total number of aluminum atoms and yttrium atoms is equal to or less than 80%. In this case, the aluminum yttrium nitride layer tends to have a wurtzite crystal structure.
<11> In <10>, in the aluminum yttrium nitride layer, the ratio of the number of yttrium atoms to the total number of aluminum atoms and yttrium atoms is equal to or greater than 10% and equal to or less than 80%.

### DETAILS OF EMBODIMENTS OF DISCLOSURE

Embodiments of the present disclosure will be described in detail below, but the present disclosure is not limited those embodiments. In the specification and the drawings, components having substantially the same functional configuration may be denoted by the same reference numerals, thereby eliminating redundant descriptions. In the present disclosure, a “plan view” means viewing an object from above. In the present disclosure, the direction in which a nitride semiconductor layer is positioned as seen from a substrate is referred to as “above”.

### First Embodiment

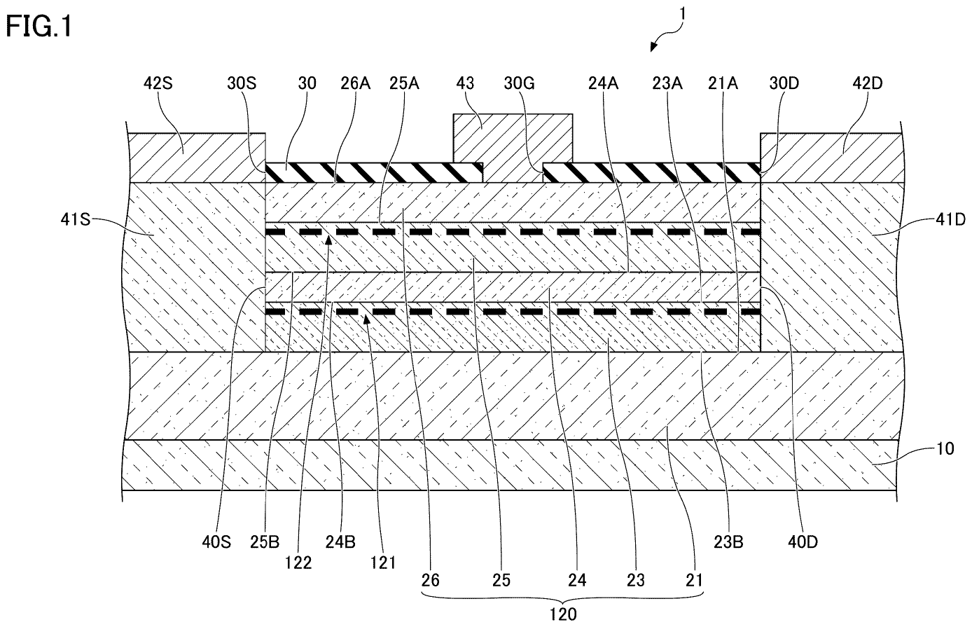

The first embodiment relates to a nitride semiconductor transistor. The nitride semiconductor transistor is, for example, a gallium nitride-based high electron mobility transistor (HEMT). FIG. 1 is a cross-sectional view illustrating a nitride semiconductor transistor according to the first embodiment.

As illustrated in FIG. 1, a nitride semiconductor transistor 1 according to the first embodiment includes a substrate 10, a nitride semiconductor layer 120, an insulating film 30, a regrowth layer 41S, a regrowth layer 41D, a gate electrode 43, a source electrode 42S, and a drain electrode 42D.

The substrate 10 is, for example, a semi-insulating silicon carbide (SiC) substrate. In the case where the substrate 10 is a SiC substrate, the upper surface of the substrate 10 is a carbon (C) polar surface.

The nitride semiconductor layer 120 includes a buffer layer 21, a channel layer 23, a ferroelectric nitride semiconductor layer 24, a channel layer 25, and a barrier layer 26. The nitride semiconductor layer 120 may include a nucleation layer between the substrate 10 and the buffer layer 21.

The buffer layer 21 is above the substrate 10. The buffer layer 21 has an upper surface 21A with a nitrogen polarity. The buffer layer 21 is, for example, a gallium nitride (GaN) layer. The thickness of the buffer layer 21 is, for example, equal to or greater than 100 nm and equal to or less than 2000 nm.

The channel layer 23 is on the upper surface 21A of the buffer layer 21. The channel layer 23 has an upper surface 23A with a nitrogen polarity and a lower surface 23B opposite to the upper surface 23A. The channel layer 23 has a polarization oriented from the lower surface 23B to the upper surface 23A. The channel layer 23 is, for example, a gallium nitride (GaN) layer. The thickness of the channel layer 23 is, for example, equal to or greater than 5 nm and equal to or less than 40 nm. The conductivity type of the channel layer 23 is, for example, n-type or undoped (i-type). The channel layer 23 is an example of a first channel layer. The upper surface 23A is an example of a first upper surface, and the lower surface 23B is an example of a first lower surface. The buffer layer 21 and the channel layer 23 need not be distinguished.

The ferroelectric nitride semiconductor layer 24 is on the upper surface 23A of the channel layer 23. The ferroelectric nitride semiconductor layer 24 has an upper surface 24A and a lower surface 24B opposite to the upper surface 24A. The upper surface 24A has a metal polarity and the lower surface 24B has a nitrogen polarity. The ferroelectric nitride semiconductor layer 24 has a polarization oriented from the upper surface 24A to the lower surface 24B. The ferroelectric nitride semiconductor layer 24 is, for example, an aluminum scandium nitride (ScAlN) layer. The thickness of the ferroelectric nitride semiconductor layer 24 is, for example, equal to or greater than 5 nm and equal to or less than 40 nm. The composition of the ferroelectric nitride semiconductor layer 24 is, for example, Sc_{X}Al_{1-X} N (0<X≤0.4). In other words, in the ScAlN layer, the ratio of the number of Sc atoms to the total number of Al atoms and Sc atoms (Sc composition ratio) is equal to or greater than 0% and equal to or less than 40%. The upper surface 24A is an example of the second upper surface.

The channel layer 25 is on the upper surface 24A of the ferroelectric nitride semiconductor layer 24. The channel layer 25 has an upper surface 25A with a metal polarity and a lower surface 25B opposite to the upper surface 25A. The channel layer 25 has a polarization oriented from the upper surface 25A to the lower surface 25B. The channel layer 25 is, for example, a gallium nitride (GaN) layer. The thickness of the channel layer 25 is, for example, equal to or greater than 5 nm and equal to or less than 40 nm. The conductivity type of the channel layer 25 is, for example, n-type or undoped (i-type). The channel layer 25 is an example of a second channel layer. The upper surface 25A is an example of a third upper surface, and the lower surface 25B is an example of a second lower surface.

The barrier layer 26 is on the upper surface 25A of the channel layer 25. The barrier layer 26 has an upper surface 26A with a metal polarity. The barrier layer 26 is, for example, an aluminum gallium nitride (AlGaN) layer. The electron affinity of the barrier layer 26 is smaller than that of the channel layer 25. The band gap of the barrier layer 26 is larger than that of the channel layer 25. The thickness of the barrier layer 26 is, for example, equal to or greater than 5 nm and equal to or less than 40 nm. The composition of the barrier layer 26 is, for example, AlYGa_{1-Y}N (0.15≤Y≤0.55). In other words, in the AlGaN layer, the ratio of the number of Al atoms to the total number of Al atoms and Ga atoms (Al composition ratio) is equal to or greater than 15% and equal to or less than 55%. The conductivity type of the barrier layer 26 is, for example, n-type or undoped (i-type). The barrier layer 26 is an example of a first barrier layer. The upper surface 26A is an example of a fourth upper surface.

In the nitride semiconductor layer 120, a recess 40S for source and a recess 40D for drain are formed. The recess 40S and the recess 40D penetrate the barrier layer 26, the channel layer 25, and the ferroelectric nitride semiconductor layer 24. The bottom of the recess 40S and the bottom of the recess 40D are closer to the lower surface of the nitride semiconductor layer 120 than to the upper surface 23A of the channel layer 23. In other words, the recess 40S and the recess 40D are formed deeper than the upper surface 23A of the channel layer 23. The recess 40S and the recess 40D may further penetrate the channel layer 23. The bottom of the recess 40S and the bottom of the recess 40D may be in the channel layer 23 or in the buffer layer 21.

The insulating film 30 is on the upper surface 26A of the barrier layer 26. The insulating film 30 is, for example, a silicon nitride (SiN) film. The thickness of the insulating film 30 is, for example, equal to or greater than 5 nm and equal to or less than 100 nm. An opening 30S for source, an opening 30D for drain, and an opening 30G for gate are formed in the insulating film 30. The opening 30S and the recess 40S communicate, and the opening 30D and the recess 40D communicate. In a plan view, the opening 30G is positioned between the opening 30S and the opening 30D. The opening 30G reaches the barrier layer 26.

In the recess 40S, the regrowth layer 41S is on the buffer layer 21 or the channel layer 23. In the recess 40D, the regrowth layer 41D is on the buffer layer 21 or the channel layer 23. The regrowth layer 41S and the regrowth layer 41D are, for example, n-type GaN layers. The regrowth layer 41S and the regrowth layer 41D contain germanium (Ge) or silicon (Si) as n-type impurities.

The source electrode 42S is on the regrowth layer 41S, and the drain electrode 42D is on the regrowth layer 41D. The source electrode 42S is in contact with the regrowth layer 41S, and the drain electrode 42D is in contact with the regrowth layer 41D. The source electrode 42S has an ohmic contact with the regrowth layer 41S, and the drain electrode 42D has an ohmic contact with the regrowth layer 41D.

In a plan view, the gate electrode 43 is positioned between the source electrode 42S and the drain electrode 42D. The gate electrode 43 is on the insulating film 30 and in contact with the barrier layer 26 via the opening 30G.

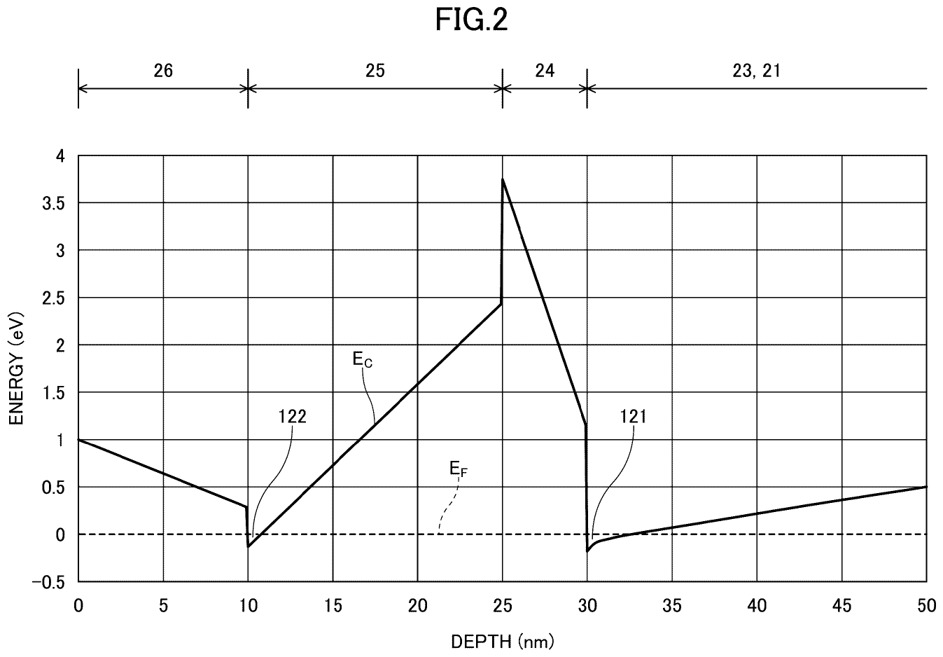

Herein, an example of a band structure of the nitride semiconductor transistor 1 will be described. FIG. 2 is a diagram illustrating a band structure of the nitride semiconductor transistor 1 according to the first embodiment. FIG. 2 illustrates a Fermi level E_{F} and the bottom E_{C} of a conduction band. In FIG. 2, the horizontal axis indicates a depth with reference to the upper surface 26A of the barrier layer 26, and the vertical axis indicates an energy with reference to the Fermi level E_{F}. In the example illustrated in FIG. 2, the buffer layer 21 and the channel layer 23 are GaN layers having a total thickness of 20 nm or greater, the ferroelectric nitride semiconductor layer 24 is a Sc_{0.2}Al_{0.8}N layer having a thickness of 5 nm, the channel layer 25 is a GaN layer having a thickness of 15 nm, and the barrier layer 26 is an Al_{0.3}Ga_{0.7}N layer having a thickness of 10 nm.

In the nitride semiconductor transistor 1, the upper surface 23A of the channel layer 23 has a nitrogen polarity, the upper surface 24A of the ferroelectric nitride semiconductor layer 24 has a metal polarity, and the lower surface 24B has a nitrogen polarity. For this reason, as illustrated in FIGS. 1 and 2, a two-dimensional electron gas (2DEG) 121 is generated near the upper surface 23A of the channel layer 23. In other words, the channel layer 23 includes the two-dimensional electron gas 121 at a position closer to the upper surface 23A than to the lower surface 23B. The upper surface 25A of the channel layer 25 has a metal polarity, and the upper surface 26A of the barrier layer 26 has a metal polarity. For this reason, as illustrated in FIGS. 1 and 2, a two-dimensional electron gas 122 is generated near the upper surface 25A of the channel layer 25. In other words, the channel layer 25 includes the two-dimensional electron gas 122 at a position closer to the upper surface 25A than to the lower surface 25B. The two-dimensional electron gas 121 is generated mainly by spontaneous polarization of the ferroelectric nitride semiconductor layer 24, and the two-dimensional electron gas 122 is generated mainly by spontaneous polarization of the barrier layer 26. The two-dimensional electron gas 121 is an example of a first two-dimensional electron gas, and the two-dimensional electron gas 122 is an example of a second two-dimensional electron gas.

The plane of polarity of the nitride semiconductor layer can be specified, for example, by using an annular bright-field scanning transmission electron microscope (ABF-STEM).

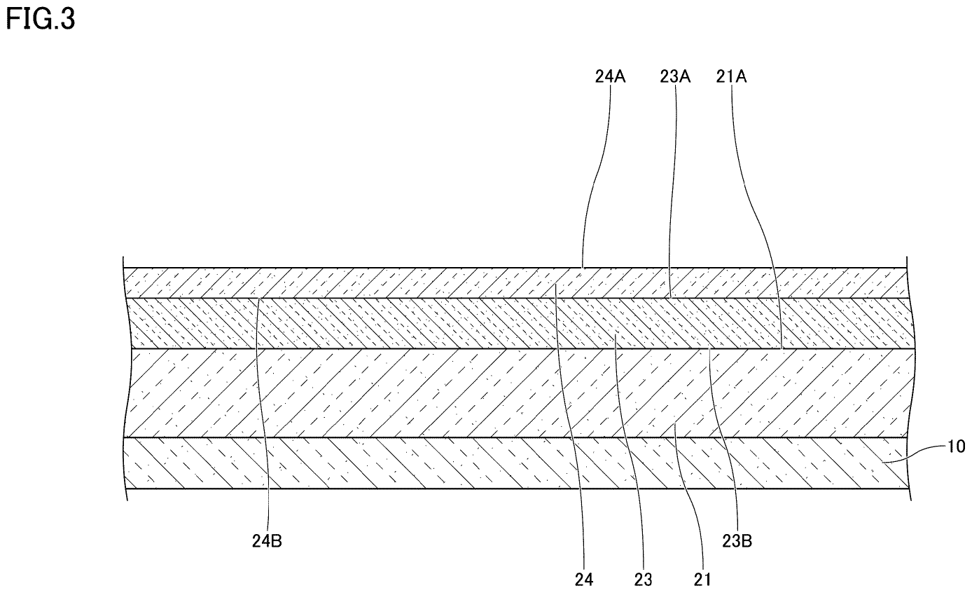

Next, a method of manufacturing the nitride semiconductor transistor 1 according to the first embodiment will be described. FIGS. 3 through 8 are cross-sectional views illustrating a method of manufacturing the nitride semiconductor transistor 1 according to the first embodiment.

First, as illustrated in FIG. 3, the buffer layer 21, the channel layer 23, and the ferroelectric nitride semiconductor layer 24 are sequentially formed on the substrate 10 by, for example, a metal-organic chemical vapor deposition (MOCVD) method. After the buffer layer 21 and the channel layer 23 are formed by the MOCVD method, the ferroelectric nitride semiconductor layer 24 may be formed by, for example, a sputtering method or a molecular beam epitaxy (MBE) method. At this point, the upper surface 21A of the buffer layer 21, the upper surface 23A of the channel layer 23, and the upper surface 24A of the ferroelectric nitride semiconductor layer 24 have a nitrogen polarity.

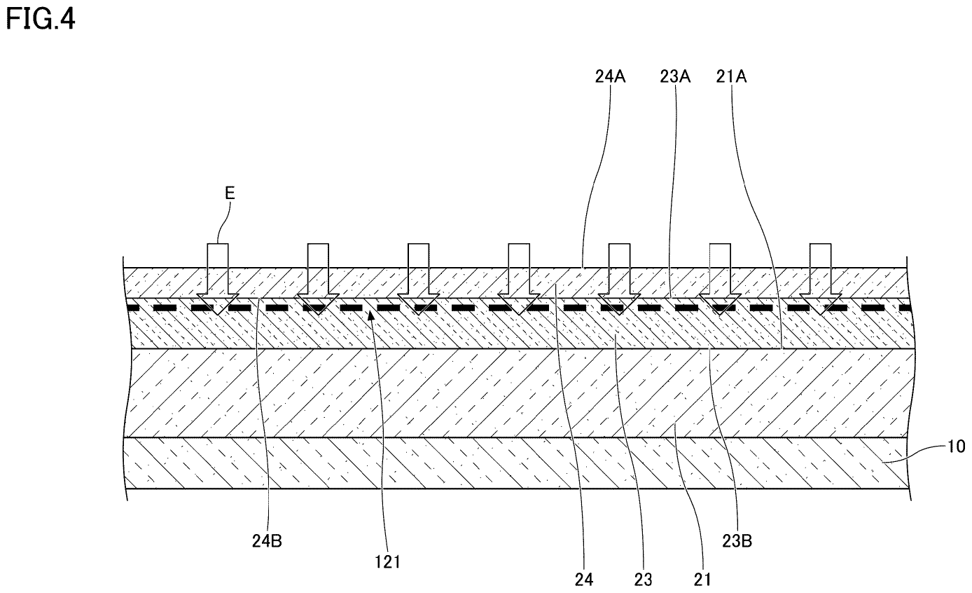

Next, as illustrated in FIG. 4, an electric field E larger than the coercive field of the ferroelectric nitride semiconductor layer 24 is applied to the ferroelectric nitride semiconductor layer 24, thereby reversing the polarization orientation of the ferroelectric nitride semiconductor layer 24. As a result, the arrangement of atoms in the ferroelectric nitride semiconductor layer 24 is changed, and the upper surface 24A of the ferroelectric nitride semiconductor layer 24 has a metal polarity and the lower surface 24B has a nitrogen polarity. A two-dimensional electron gas 121 is generated in the vicinity of the upper surface 23A of the channel layer 23. The electric field E can be applied, for example, by corona discharge or applying a voltage between two electrodes (not illustrated). When the polarization orientation is reversed, the ferroelectric nitride semiconductor layer 24 may be heated to a temperature of about 500° C. or lower. The ferroelectric nitride semiconductor layer 24 may include a part in which the polarization is not reversed. It should be noted that there may be a part of the ferroelectric nitride semiconductor layer 24 in which the polarization is not reversed.

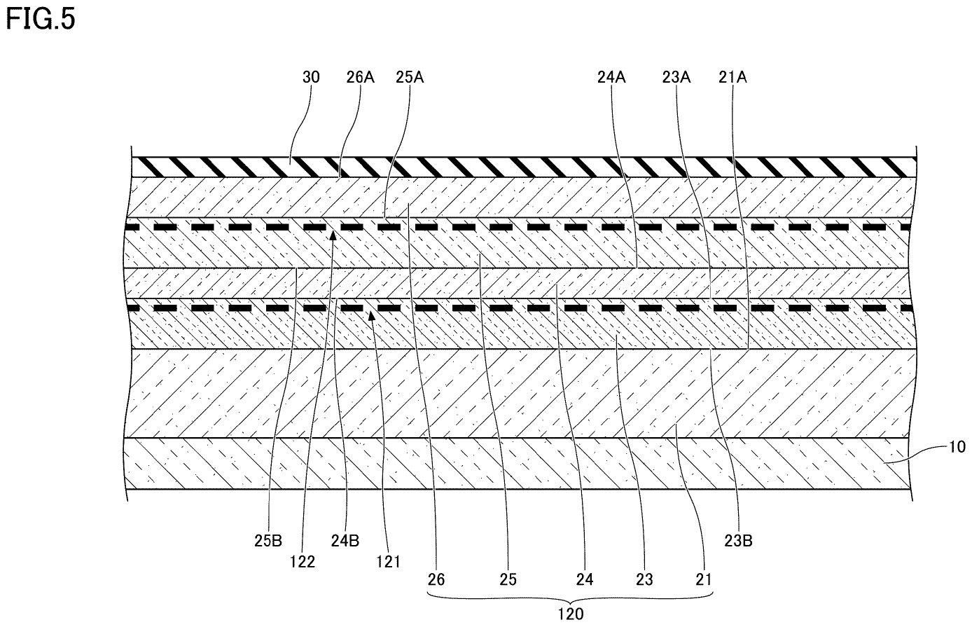

Next, as illustrated in FIG. 5, the channel layer 25 and the barrier layer 26 are sequentially formed on the ferroelectric nitride semiconductor layer 24 by, for example, the MOCVD method. Next, the insulating film 30 is formed on the barrier layer 26.

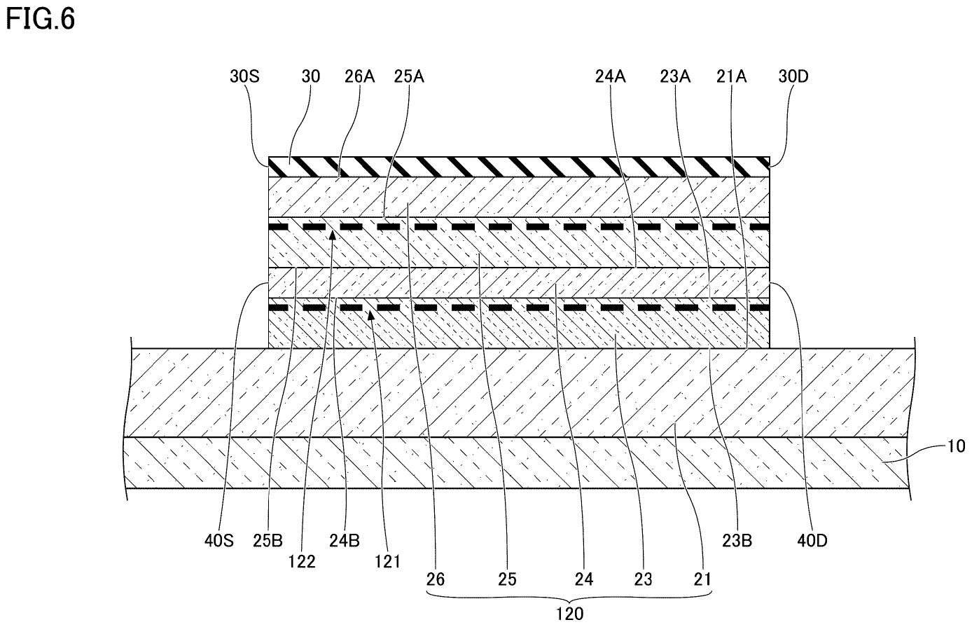

Next, as illustrated in FIG. 6, an opening 30S for source and an opening 30D for drain are formed in the insulating film 30, and a recess 40S for source and a recess 40D for drain are formed in the nitride semiconductor layer 120. The opening 30S, the opening 30D, the recess 40S and the recess 40D can be formed by, for example, reactive ion etching (RIE) using a mask (not illustrated) or ion milling.

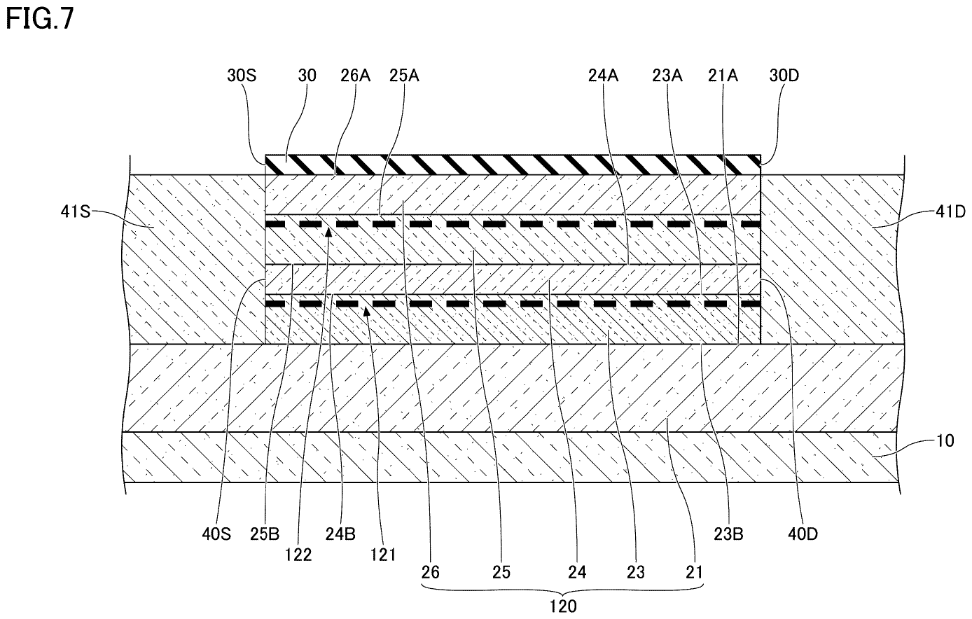

Next, as illustrated in FIG. 7, the regrowth layer 41S is formed on the buffer layer 21 or the channel layer 23 in the recess 40S, and the regrowth layer 41D is formed on the buffer layer 21 or the channel layer 23 in the recess 40D. The regrowth layer 41S and the regrowth layer 41D can be formed by, for example, a physical vapor deposition (PVD) method (for example, a vapor deposition method, a sputtering method, or an MBE method) or an MOCVD method.

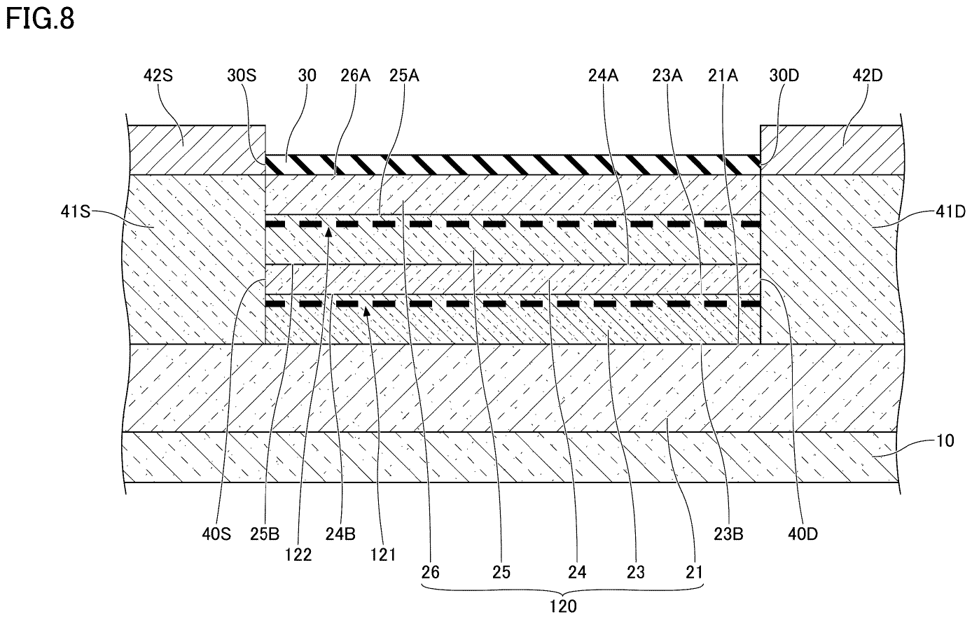

Next, as illustrated in FIG. 8, the source electrode 42S is formed on the regrowth layer 41S, and the drain electrode 42D is formed on the regrowth layer 41D. To form the source electrode 42S and the drain electrode 42D, first, a metal layer (not illustrated) constituting the source electrode 42S and the drain electrode 42D is formed. To form the metal layer, for example, a film is formed using a growth mask (not illustrated) having an opening formed in a region where the metal layer is to be formed, and then the growth mask is removed together with the metal layer (not illustrated) formed thereon. In other words, lift-off is performed.

Next, an opening 30G for gate is formed in the insulating film 30 (see FIG. 1). The opening 30G can be formed, for example, by RIE using a mask (not illustrated). Next, a gate electrode 43 to be in contact with the barrier layer 26 via the opening 30G is formed on the insulating film 30 (see FIG. 1). To form the gate electrode 43, for example, a metal layer is formed using a growth mask (not illustrated) having an opening formed in a region where the gate electrode 43 is to be formed, and then the growth mask is removed together with the metal layer (not illustrated) formed thereon. In other words, lift-off is performed.

The nitride semiconductor transistor 1 can be thereby manufactured.

The method and timing for inverting the polarization of the ferroelectric nitride semiconductor layer 24 are not particularly limited.

### Second Embodiment

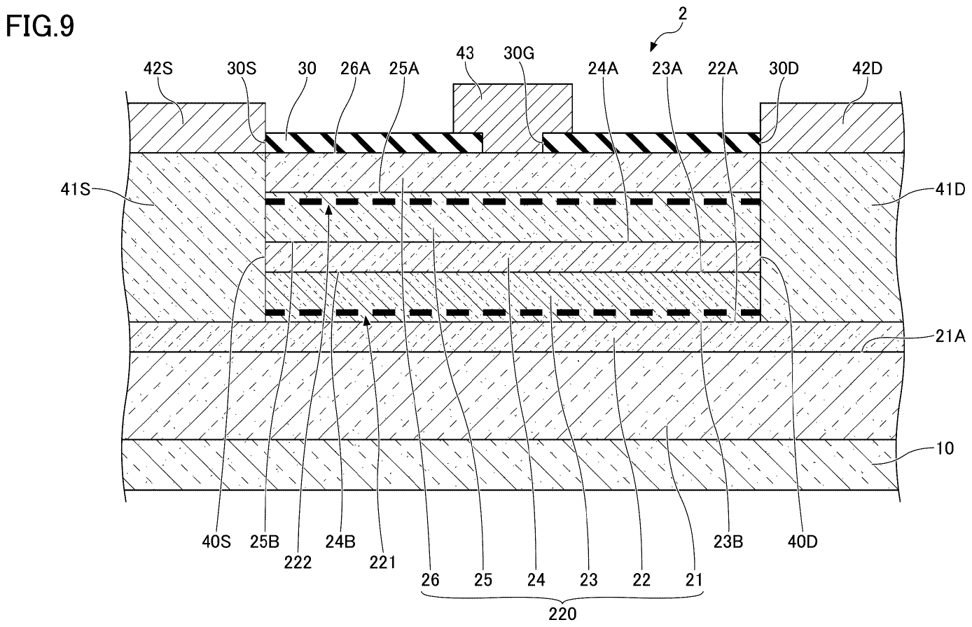

The second embodiment differs from the first embodiment mainly in the structure of the nitride semiconductor layer. FIG. 9 is a cross-sectional view illustrating a nitride semiconductor transistor according to the second embodiment.

As illustrated in FIG. 9, a nitride semiconductor transistor 2 according to the second embodiment has a nitride semiconductor layer 220 instead of the nitride semiconductor layer 120.

The nitride semiconductor layer 220 includes the buffer layer 21, a barrier layer 22, the channel layer 23, the ferroelectric nitride semiconductor layer 24, the channel layer 25, and the barrier layer 26. The nitride semiconductor layer 220 may include a nucleation layer between the substrate 10 and the buffer layer 21.

The barrier layer 22 is on the upper surface 21A of the buffer layer 21. The barrier layer 22 has an upper surface 22A with a nitrogen polarity. The channel layer 23 is on the upper surface 22A of the barrier layer 22. The barrier layer 22 is, for example, an aluminum gallium nitride (AlGaN) layer. The electron affinity of the barrier layer 22 is smaller than that of the channel layer 23. The band gap of the barrier layer 22 is larger than that of the channel layer 23. The thickness of the barrier layer 22 is, for example, equal to or greater than 5 nm and equal to or less than 40 nm. The composition of the barrier layer 22 is, for example, AlZGa_{1-Z}N (0.15≤Z≤0.55). In other words, in the AlGaN layer, the ratio of the number of Al atoms to the total number of Al atoms and Ga atoms (Al composition ratio) is equal to or greater than 15% and equal to or less than 55%. The conductivity type of the barrier layer 22 is, for example, n-type or undoped (i-type). The barrier layer 22 is an example of a second barrier layer. The upper surface 22A is an example of a fifth upper surface.

The recess 40S and the recess 40D penetrate the barrier layer 26, the channel layer 25, the ferroelectric nitride semiconductor layer 24, and the channel layer 23. The recess 40S and the recess 40D may further penetrate the barrier layer 22. The bottom of the recess 40S and the bottom of the recess 40D may be in the barrier layer 22 or in the buffer layer 21. In the recess 40S, the regrowth layer 41S is on the barrier layer 22 or the buffer layer 21. In the recess 40D, the regrowth layer 41D is on the barrier layer 22 or the buffer layer 21.

Other structures of the nitride semiconductor transistor 2 are the same as those of the nitride semiconductor transistor 1.

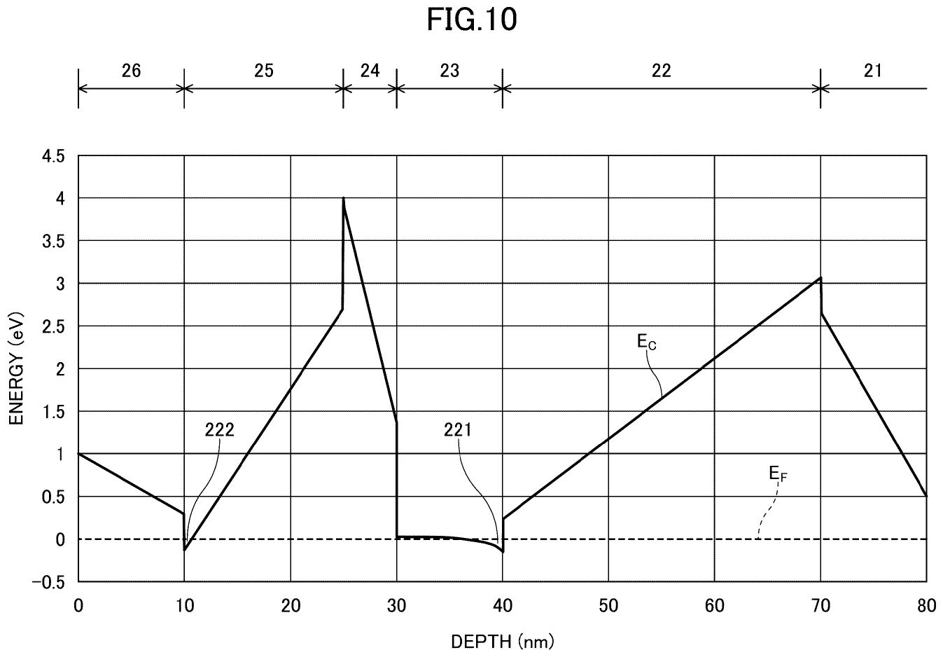

Herein, an example of a band structure of the nitride semiconductor transistor 2 will be described. FIG. 10 is a diagram illustrating a band structure of the nitride semiconductor transistor 2 according to the second embodiment. FIG. 10 illustrates a Fermi level E_{F} and the bottom E_{C} of a conduction band. In FIG. 10, the horizontal axis indicates a depth with reference to the upper surface 26A of the barrier layer 26, and the vertical axis indicates an energy with reference to the Fermi level E_{F}. In the example illustrated in FIG. 10, the buffer layer 21 is a GaN layer having a thickness of 10 nm or greater, the barrier layer 22 is an Al_{0.3}Ga_{0.7}N layer having a thickness of 30 nm, the channel layer 23 is a GaN layer having a thickness of 10 nm, the ferroelectric nitride semiconductor layer 24 is a Sc_{0.2}Al_{0.8}N layer having a thickness of 5 nm, the channel layer 25 is a GaN layer having a thickness of 15 nm, and the barrier layer 26 is an Al_{0.3}Ga_{0.7}N layer having a thickness of 10 nm.

In the nitride semiconductor transistor 2, the upper surface 22A of the barrier layer 22 has a nitrogen polarity, and the upper surface 23A of the channel layer 23 has a nitrogen polarity. For this reason, as illustrated in FIGS. 9 and 10, a two-dimensional electron gas 221 is generated near the lower surface 23B of the channel layer 23. In other words, the channel layer 23 includes the two-dimensional electron gas 221 at a position closer to the lower surface 23B than to the upper surface 23A. The upper surface 25A of the channel layer 25 has a metal polarity, and the upper surface 26A of the barrier layer 26 has a metal polarity. For this reason, as illustrated in FIGS. 9 and 10, a two-dimensional electron gas 222 is generated near the upper surface 25A of the channel layer 25. In other words, the channel layer 25 includes the two-dimensional electron gas 222 at a position closer to the upper surface 25A than to the lower surface 25B. The two-dimensional electron gas 221 is generated mainly by spontaneous polarization of the barrier layer 22, and the two-dimensional electron gas 222 is generated mainly by spontaneous polarization of the barrier layer 26. The two-dimensional electron gas 221 is an example of a first two-dimensional electron gas, and the two-dimensional electron gas 222 is an example of a second two-dimensional electron gas.

The composition of the ferroelectric nitride semiconductor layer 24 is not limited. In the case where the ferroelectric nitride semiconductor layer 24 and the channel layer 25 are lattice-matched, a compressive strain to the channel layer 25 due to a lattice mismatch between the ferroelectric nitride semiconductor layer 24 and the channel layer 25 does not occur, and a decrease in the mobility of electrons in the two-dimensional electron gas 122 or 222 caused by the compressive strain can be avoided.

The ferroelectric nitride semiconductor layer 24 may contain yttrium (Y) instead of scandium (Sc), or may contain both scandium and yttrium. In other words, the ferroelectric nitride semiconductor layer 24 may contain aluminum and at least one kind selected from the group consisting of scandium and yttrium. In this case, a large remanent polarization is easily obtained in the ferroelectric nitride semiconductor layer 24. The ferroelectric nitride semiconductor layer 24 may further contain gallium (Ga) or indium (In). In the case where the ferroelectric nitride semiconductor layer 24 contains gallium, the coercive field of the ferroelectric nitride semiconductor layer 24 can be lowered. The lattice constants of various nitrides in the a-axis direction are as shown in Table 1.

TABLE 1

| | Lattice |
|---|---|
| Nitride | Constant (Å) |
| GaN | 3.200 |
| AlGaN | 3.110 |
| Sc_{0.1}Al_{0.9}N | 3.151 |
| Sc_{0.2}Al_{0.8}N | 3.197 |
| Sc_{0.2023}Al_{0.7977}N | 3.200 |
| Sc_{0.3}Al_{0.7}N | 3.248 |
| Y_{0.1}Al_{0.9}N | 3.196 |
| Y_{0.1030}Al_{0.8970}N | 3.200 |
| Y_{0.2}Al_{0.8}N | 3.278 |
| Y_{0.3}Al_{0.7}N | 3.357 |

Sc_{X}Al_{1-X}N contained in the ferroelectric nitride semiconductor layer 24 is an example of a first nitride, and the lattice constant of Sc_{X}Al_{1-X}N is an example of a first lattice constant. GaN contained in the channel layer 25 is an example of a second nitride, and the lattice constant of GaN is an example of a second lattice constant. When the ratio of the first lattice constant to the second lattice constant is equal to or greater than 99%, a compressive strain to the channel layer 25 due to a lattice mismatch between the ferroelectric nitride semiconductor layer 24 and the channel layer 25 is less likely to occur, and a decrease in electron mobility in the two-dimensional electron gas 122 or 222 caused by the compressive strain is easily avoidable.

Even if the channel layer 23 and the ferroelectric nitride semiconductor layer 24 have different lattice constants, if the thickness of the ferroelectric nitride semiconductor layer 24 is equal to or less than a critical film thickness, the interatomic distance in the ferroelectric nitride semiconductor layer 24 is approximately equal to the interatomic distance in the channel layer 23. Therefore, if both the channel layer 23 and the channel layer 25 are GaN layers, the interatomic distance in the channel layer 25 is approximately equal to the interatomic distance in the ferroelectric nitride semiconductor layer 24, and the stress caused by the lattice strain does not appreciably act on the channel layer 25.

In the case where the ferroelectric nitride semiconductor layer 24 is an aluminum scandium nitride layer, the aluminum scandium nitride layer tends to have a wurtzite crystal structure if the ratio of the number of Sc atoms to the total number of Al atoms and Sc atoms (Sc composition ratio) in the aluminum scandium nitride layer is equal to or less than 40%. When the ratio of the number of Sc atoms is equal to or greater than 10% and equal to or less than 40%, a compressive strain to the channel layer 25 due to a lattice mismatch between the ferroelectric nitride semiconductor layer 24 and the channel layer 25 is less likely to occur, and a decrease in electron mobility in the two-dimensional electron gas 122 or 222 caused by the compressive strain is easily avoidable.

In the case where the ferroelectric nitride semiconductor layer 24 is an yttrium scandium nitride layer, the aluminum yttrium nitride layer tends to have a wurtzite crystal structure if the ratio of the number of Y atoms to the total number of Al atoms and Y atoms (Y composition ratio) in the aluminum scandium nitride layer is equal to or less than 80%. When the ratio of the number of Y atoms is equal to or greater than 10% and equal to or less than 80%, a compressive strain to the channel layer 25 due to a lattice mismatch between the ferroelectric nitride semiconductor layer 24 and the channel layer 25 is less likely to occur, and a decrease in electron mobility in the two-dimensional electron gas 122 or 222 caused by the compressive strain is easily avoidable.

The Sc composition ratio and the Y composition ratio can be measured, for example, by transmission electron microscopy energy dispersive X-ray spectroscopy (TEM-EDX), secondary ion mass spectrometry (SIMS), or X-ray photoelectron spectroscopy.

Although the embodiments have been described in detail, the present disclosure is not limited to such specific embodiments, and various modifications and changes can be made within the scope described in the claims.

What is claimed is:

1. A nitride semiconductor transistor, comprising:
a first channel layer having a first upper surface with a nitrogen polarity;
a ferroelectric nitride semiconductor layer deposited on the first upper surface and having a second upper surface with a first metal polarity;
a second channel layer deposited on the second upper surface and having a third upper surface with a second metal polarity; and
a first barrier layer deposited on the third upper surface and having a fourth upper surface with a third metal polarity.

2. The nitride semiconductor transistor according to claim 1, wherein
the ferroelectric nitride semiconductor layer includes
aluminum; and
at least one selected from the group consisting of scandium and yttrium.

3. The nitride semiconductor transistor according to claim 1, wherein
the first channel layer has a first lower surface opposite to the first upper surface,
the second channel layer has a second lower surface opposite to the third upper surface,
the first channel layer includes a first two-dimensional electron gas closer to the first upper surface than to the first lower surface, and
the second channel layer includes a second two-dimensional electron gas closer to the third upper surface than to the second lower surface.

4. The nitride semiconductor transistor according to claim 1, further comprising:
a second barrier layer having a fifth upper surface with a nitrogen polarity, wherein
the first channel layer is deposited on the second barrier layer.

5. The nitride semiconductor transistor according to claim 4, wherein
the first channel layer has a first lower surface opposite to the first upper surface,
the second channel layer has a second lower surface opposite to the third upper surface,
the first channel layer includes a first two-dimensional electron gas closer to the first lower surface than to the first upper surface, and
the second channel layer includes a second two-dimensional electron gas closer to the third upper surface than to the second lower surface.

6. The nitride semiconductor transistor according to claim 1, wherein
the ferroelectric nitride semiconductor layer and the second channel layer are lattice-matched.

7. The nitride semiconductor transistor according to claim 1, wherein
the ferroelectric nitride semiconductor layer includes a first nitride having a first lattice constant,
the second channel layer includes a second nitride having a second lattice constant, and
a ratio of the first lattice constant to the second lattice constant is equal to or greater than 99%.

8. The nitride semiconductor transistor according to claim 1, wherein
the ferroelectric nitride semiconductor layer is an aluminum scandium nitride layer, and
in the aluminum scandium nitride layer, a ratio of a number of scandium atoms to a total number of aluminum atoms and scandium atoms is equal to or less than 40%.

9. The nitride semiconductor transistor according to claim 8, wherein
in the aluminum scandium nitride layer, a ratio of a number of scandium atoms to a total number of aluminum atoms and scandium atoms is equal to or greater than 10% and equal to or less than 40%.

10. The nitride semiconductor transistor according to claim 1, wherein
the ferroelectric nitride semiconductor layer is an aluminum yttrium nitride layer, and
in the aluminum yttrium nitride layer, a ratio of a number of yttrium atoms to a total number of aluminum atoms and yttrium atoms is equal to or less than 80%.

11. The nitride semiconductor transistor according to claim 10, wherein
in the aluminum yttrium nitride layer, the ratio of the number of yttrium atoms to the total number of aluminum atoms and yttrium atoms is equal to or greater than 10% and equal to or less than 808.
